(19) United States
(12) Patent Application Publication
(10) Pub. No.: US 2018/0138455 A1
(43) Pub. Date: May 17, 2018

(54) ENCAPSULATION METHOD FOR OLED LIGHTING APPLICATION

(71) Applicant: SABIC Global Technologies B.V., Bergen op Zoom (NL)

(72) Inventor: Sang Hoon KIM, Seoul (KR)

(21) Appl. No.: 15/569,791

(22) PCT Filed: Apr. 25, 2016
(86) PCT No.: PCT/IB2016/052336

§ 371 Date: Oct. 27, 2017

Related U.S. Application Data
(60) Provisional application No. 62/154,401, filed on Apr. 29, 2015.

(51) Int. Cl. H01L 51/52; H01L 51/00; H01L 51/56

(52) U.S. Cl. CPC H01L 51/5271; H01L 51/5259; H01L 2251/5338; H01L 51/56; H01L 51/0097

(57) ABSTRACT

The OLED assembly including an OLED structure (20) and a metallic frame (30) is disclosed. The metallic frame (30) is arranged around the OLED structure (20) and covers the lateral surfaces (25) of the OLED structure. The OLED structure has lateral surfaces and includes a flexible substrate (40), an OLED (50) disposed on the flexible substrate, and a desiccant layer (60) surrounding the OLED. The OLED includes a first electrode (52), a second electrode (54) and an organic electroluminescent layer (56) disposed between the first and second electrodes.

### RELATED APPLICATIONS

The application claims benefit of U.S. Patent Application No. 62/154,401 filed on Apr. 29, 2015, the disclosure of which is incorporated herein in its entirety.

### TECHNICAL FIELD

The disclosure generally relates to methods and structures for preventing the transmission of moisture and gas to organic light emitting devices (OLEDs), and more particularly to methods and structures utilizing a metallic frame to prevent the transmission of moisture and gas through the lateral surfaces of OLEDs and to improve the light efficiency of OLEDs,

### BACKGROUND

Organic light emitting devices (OLEDs) typically comprise a laminate formed on a. substrate such as glass or silicon. A light-emitting layer of a. luminescent organic solid, as well as optional adjacent semiconductor layers, is sandwiched between a cathode and an anode. The semiconductor layers may be hole-injecting or electron-injecting layers. The light-emitting layer may be selected from any of a multitude of fluorescent organic solids. The light-emitting layer may consist of multiple sublayers or a single blended layer,

When a potential difference is applied across the anode and cathode, electrons move from the cathode to the optional electron-injecting layer and finally into the layer(s) of organic material. At the same time, holes move from the anode to the optional hole-injecting layer and finally into the same organic light-emitting layer(s). When the holes and electrons meet in the layer(s) of organic material, they combine, and produce photons. The wavelength of the photons depends on the material properties of the organic material in which the photons are generated. The color of light emitted from the OLED can be controlled by the selection of the organic material, or by the selection of dopants, or by other techniques known in the art. Different colored light may be generated by mixing the emitted light from different OLEDs. For example, white light can be produced by mixing blue, red, and green light.

In a typical OLED, either the anode or the cathode is transparent in order to allow the emitted light to pass through. If it is desirable to allow light to be emitted from both sides of the OLED, both the anode and cathode can be transparent.

The basic OLED has a structure in which an anode, an organic light emitting layer, and a cathode are consecutively laminated, with the organic light emitting layer sandwiched between the anode and the cathode. Generally, electrical current flowing between the anode and cathode passes through points of the organic light emitting layer and causes it to luminesce. The electrode positioned on the surface through which light is emitted is formed of a transparent or semi-transparent film. The other electrode is formed of a specific thin metal film, which can be a metal or an alloy.

OLEDs typically have a number of beneficial characteristics, including a low activation voltage (about 5 volts), fast response when formed with a thin light-emitting layer, high brightness in proportion to the injected electric current, high visibility due to self-emission, superior impact resistance, and ease of handling of the solid state devices in which they are used. OLEDs have practical application in television, graphic display systems, digital printing and lighting. Although substantial progress has been made in the development of OLEDs to date, additional challenges remain. For example, OLEDs continue to face challenges associated with their long-term stability. In particular, during operation the layers of organic film may undergo recrystallization or other structural changes that adversely affect the emissive properties of the device.

One of the factors limiting the widespread use of organic light emitting devices has been the fact that the organic polymers or small molecule materials making up the device as well as, in some cases, the electrodes, are environmentally sensitive. In particular, it is well known that device performance degrades in the presence of water and oxygen. Exposing a conventional OLED to the atmosphere shortens its life. The organic material in the light-emitting layer(s) reacts with water vapor and/or oxygen. Lifetimes of 5,000 to 35,000 hours have been obtained for evaporated films and greater than 5,000 hours for polymers. However, these values are typically reported for room temperature operation in the absence of water vapor and oxygen. Lifetimes associated with operations outside these conditions are typically much shorter.

This fault tendency has especially limited the use of mechanically flexible plastic substrates for organic electroluminescent devices, because plastics are generally highly permeable to water and oxygen. Thus, mechanically flexible organic electroluminescent devices have not been available for practical applications.

Attempts have been made to coat plastics with various inorganic layers to provide a barrier to water and/or oxygen diffusion. For plastic substrates that hold the possibility of being mechanically flexible, the main efforts have involved depositing an inorganic coating such as SiO₂ or Si₃N₄ onto the plastic. However, to date, an adequate system has not been found to prevent degradation of the illumination device. The reason for this is due to imperfections such as pinholes in the inorganic coating. These imperfections provide a path for water and/or oxygen entry. It should be noted that even if an organic coating can be applied without imperfections, imperfections such as cracks often develop during thermal cycling due to the large mismatch in thermal expansion rates for plastics and inorganic coatings.

There are numerous designs of late to minimize water and oxygen diffusion into the active organic electroluminescent device region that have been utilized for rigid devices that do not utilize plastic substrates. One method is to fabricate the device on a glass substrate and then to sandwich it between another glass slide. In this design, because glass has excellent barrier properties for water and oxygen, the weak point in the design is usually the material used to join the glass substrate to slide. Another method is to fabricate the device on a glass substrate and then to encase the whole device in an airtight chamber filled with a desiccant/drying agent. Another method described is to encase the device in an inert liquid barrier layer. Yet another method involves forming thin-film passivation layers composed of an insulating film in order to encapsulate the OLED. Although the passivation layers may protect the encapsulated OLED, there are many issues with controlling defects and the layer thickness. Although these designs are useful to some extent, they are generally not appropriate for flexible substrates. These conventional methods also fail to properly encapsulate the lateral sides or lateral surfaces of the OLED structure, which are particularly vulnerable to moisture and oxygen.

Therefore, it would be desirable to provide a structure with improved barrier properties for OLEDs that could prevent premature deterioration of the elements of the OLED due to permeated water and oxygen without interfering with the light transmission from the OLED. It would also be desirable to provide such a structure that is flexible. Accordingly, the disclosed OLED assembly and process is directed at overcoming one or more of these disadvantages in currently available OLEDs.

### SUMMARY

In accordance with one aspect of the disclosure, an OLED assembly is disclosed. The OLED assembly includes an OLED structure and a metallic frame arranged around the OLED structure wherein the metallic frame covers the lateral surfaces of the OLED structure. The OLED structure includes a flexible substrate, an OLED disposed on the flexible substrate, and a desiccant layer surrounding the OLED. The OLED includes a first electrode, a second electrode and an organic electroluminescent layer disposed between the first and second electrodes.

In accordance with another aspect of the disclosure, a process for fabricating an OLED assembly is disclosed. The process includes forming an OLED structure having lateral surfaces, including providing a flexible substrate, providing an OLED on the flexible substrate, and forming a desiccant layer surrounding the OLED, wherein the OLED includes a first electrode, a second electrode and an organic electroluminescent layer disposed between the first and second electrodes. The process further includes forming a metallic frame around the OLED structure, including covering the lateral surfaces of the OLED structure with the metallic frame.

In accordance with another aspect of the disclosure, a metallic frame for encapsulating an OLED structure is disclosed. The metallic frame is arranged around the OLED structure and covers the lateral surfaces of the OLED structure. The OLED structure has lateral surface and includes a flexible substrate, an OLED disposed on the flexible substrate, and a desiccant layer surrounding the OLED. The OLED includes a first electrode, a second electrode and an organic electroluminescent layer disposed between the first and second electrodes.

### BRIEF DESCRIPTION OF THE DRAWINGS

The above-mentioned and other features and advantages of this disclosure, and the manner of attaining them, will become apparent and be better understood by reference to the following description of one aspect of the disclosure in conjunction with the accompanying drawings, wherein:

FIG. 1 is a cross-sectional view of an OLED assembly showing a metallic frame, according to an aspect of the disclosure.

FIG. 2 is a cross-sectional view of the OLED assembly showing a patterned metallic frame, according to an aspect of the disclosure.

FIG. 3 is a block diagram of a process of fabricating an OLED assembly according to an aspect of the disclosure.

FIG. 4 is a schematic illustration of a process of fabricating an OLED assembly using lamination, according to an aspect of the disclosure.

FIG. 5 is a schematic illustration of a process of fabricating an OLED assembly using lamination, according to an aspect of the disclosure.

FIG. 6 is a schematic illustration of a process of fabricating an OLED assembly using lamination, according to an aspect of the disclosure.

FIG. 7 is a schematic illustration of a process of fabricating an OLED assembly using shadow mask deposition, according to an aspect of the disclosure.

FIG. 8 is a schematic illustration of a process of fabricating an OLED assembly using shadow mask deposition, according to an aspect of the disclosure.

FIG. 9 is a schematic illustration of a process of fabricating an OLED assembly using shadow mask deposition, according to an aspect of the disclosure.

FIG. 10 is a schematic illustration of a process of fabricating an OLED assembly using shadow mask deposition, according to an aspect of the disclosure.

### DETAILED DESCRIPTION

Assemblies for devices which are sensitive to moisture and/or gas, especially organic light emitting devices (OLEDs) with increased resistance to moisture and/or gas, are disclosed. Although the discussion of the preferred embodiments relates to OLEDs, it will be understood by those skilled in the art that the disclosure is in fact applicable to any device, especially those emitting light, which are sensitive to moisture and/or gas.

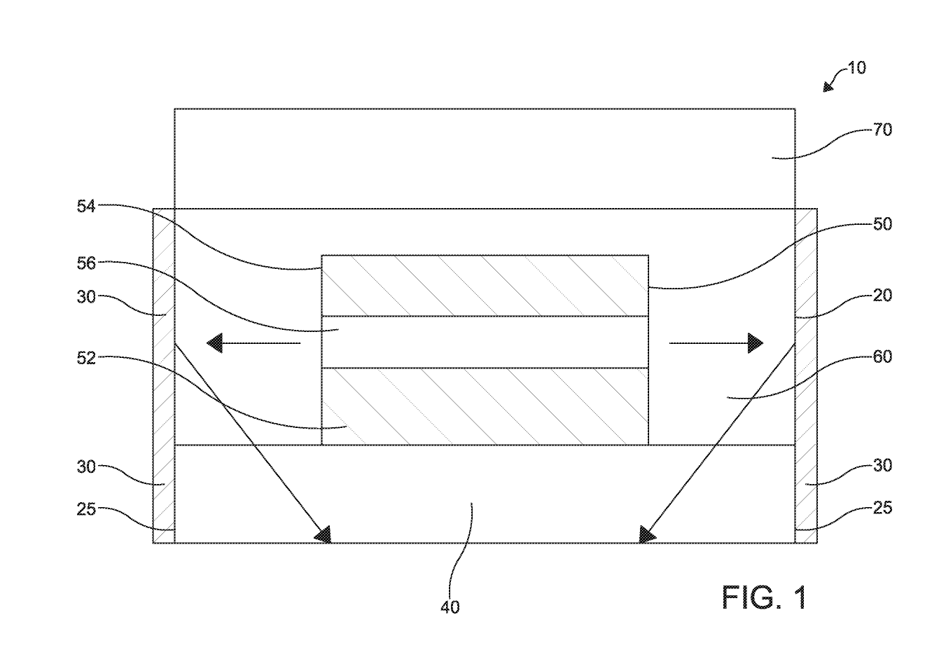

A cross-sectional view of an OLED assembly 10 according to an aspect of the disclosure is illustrated in FIG. 1. The OLED assembly 10 may include an OLED structure 20 and a metallic frame 30. As shown, the metallic frame 30 is arranged around the OLED structure 20 and covers the lateral surfaces 25 of the OLED structure 20. The OLED structure 20 may be generally planar and may have lateral surfaces 25 that extend between the top and bottom surfaces of the OLED structure 20.

The OLED structure 20 may include a flexible substrate 40, an OLED 50 and a desiccant layer 60. The OLED 50 is disposed on the flexible substrate 40. The OLED 50 may have a first electrode 52, a second electrode 54 and an organic electroluminescent layer 56 disposed between the first electrode 52 and the second electrode 54. Typically, the organic electroluminescent layer 56 comprises an electroluminescent organic solid which fluoresces when subjected to a current. Numerous such materials are known in the art, and the disclosure is not limited to a particular one. The first and second electrodes 52, 54 may be for example, an anode and a cathode used in the OLED 50, Although shown as a single layer, the first and second electrodes 52, 54 may include a plurality of sub-layers. Many electrode configurations are known and may be applied to the disclosure by one skilled in the art. The OLED 50 may have more than one electroluminescent layer 56 and the OLED structure 20 may have more than one OLED 50. The disclosure is not limited in this regard.

### Flexible Substrate

The flexible substrate 40 may be composed of an organic solid, an inorganic solid, or a combination of organic and inorganic solids. The flexible substrate 40 may be fabricated as separate individual pieces, such as sheets or wafers, or as a continuous roll. Suitable materials for the flexible substrate 40 include glass, plastic, metal, ceramic, semiconductor, metal oxide, metal nitride, metal sulfide, semiconductor oxide, semiconductor nitride, semiconductor sulfide, carbon, or combinations thereof, or any other materials commonly used to form organic light emitting devices 20. The flexible substrate 40 may be transparent or light transmissive, light absorbing or light reflective. In one aspect the disclosure, the flexible substrate 40 may be transparent or light transmissive and the OLED structure 20 may be a bottom-emitting device.

In certain aspects of the disclosure, the flexible substrate 40 may be a plastic film. Suitable plastic materials used to form the flexible substrate 40 may include polyetherimide (PEI), polycarbonate (PC), polyethylene terephthalate (PET), polyethylene naphthalate (PEN), polybutylene terephthalate (PBT) or other polyester, polyether sulfone (PES), and polyether ether ketone (PEEK). Other plastic materials, however, may be used to form plastic films for the flexible substrate 40. In some aspects of the disclosure, the flexible substrate 40 may be a multi-layered plastic film.

### Desiccant Layer

The desiccant layer 60 may surround the OLED 50 as shown in FIG. 1. The desiccant layer 60 may also surround the flexible substrate 40 in addition to the OLED 50 such that the lateral surfaces of the flexible substrate 40 are also covered by the desiccant layer 60. The desiccant layer 60 may absorb any moisture or gas that may permeate through the encapsulation layer 70 and/or the metallic frame 30 and potentially damage the OLED structure 20. The desiccant layer 60 may be transparent or light transmissive and may be used to form a top-emitting device.

The desiccant layer 60 may be composed of a desiccant material that is water absorbing and/or gas absorbing. The desiccant material may be a single material, a homogeneous mixture of materials, a composite of materials, or multiple layers of materials, and can be deposited from a vapor or from solution, or they may be provided in a porous matrix such as a permeable package or tape, Desiccant materials may include for example, alkaline metal oxides, alkaline earth metal oxides, sulfates, metal halides, and perchlorates.

The desiccant layer 60 may include an adhesive material. The adhesive material can be any number of materials, including UV or heat cured epoxy resin, acrylates, or pressure sensitive adhesive.Suitable adhesive materials for the desiccant layer 60 may include polyurethanes, acrylates, silicones, polyamides, polyolefins, and polyesters, or combinations thereof. The adhesive material can also function as a protective layer. Using an adhesive material in the desiccant layer 60 will have the further advantage that the encapsulation layer 70 or the metallic frame 30 will more easily adhere to the OLED structure 20, thereby providing a more effective seal.

### Metallic Frame

The OLED assembly 10 may include a metallic frame 30 disposed on at least one lateral surface 25 of the OLED structure 20. The lateral surfaces 25 of the OLED structure 20 extend between the top surface and the bottom surface of a generally planar OLED structure 20. For example, the OLED structure 20 may have four lateral surfaces 25 that are perpendicular to the top and bottom surfaces of the OLED structure 20. In some aspects of the disclosure, the OLED assembly 10 may include a metallic frame 30 disposed on all four lateral surfaces 25 of the organic light emitting device 20. In general, the metallic frame 30 may be flexible and does not restrict the movement of the OLED structure 20.

In one aspect of the disclosure, the metallic frame 30 may be composed of any metal that is suitable to prevent gas and/or moisture from permeating through the lateral surfaces 25 of the OLED structure 20. In one aspect of the disclosure, the metallic frame 30 may include metals such as aluminum, nickel, copper, silver, tin, gold, chromium, cobalt, and alloys of such metals. Other metals, however, are also contemplated to form the metallic frame 30. In one aspect of the disclosure, the metallic frame 30 is composed of a highly reflective metal. In another aspect of the disclosure, the metallic frame 30 is composed of a highly reflective and light transmissive metal.

The metallic frame 30 may also be composed of an organic solid, an inorganic solid, or a combination of organic and inorganic solids in addition to metal. For example, the metallic frame 30 may be formed from a polymer matrix containing metal particles. The metallic frame 30 may be fabricated as separate individual pieces, such as sheets or wafers, or as a. continuous roll, Suitable materials for the metallic frame 30 include glass, plastic, metal, ceramic, semiconductor, metal oxide, metal nitride, metal sulfide, semiconductor oxide, semiconductor nitride, semiconductor sulfide, carbon, or combinations thereof, or any other materials commonly used to form organic light emitting devices. In some aspects according to the disclosure, the metallic frame 30 may be light transmissive, light absorbing or light reflective.

The metallic frame 30 may be a film composed of a single layer or multiple layers. The metallic frame 30 may be for example composed of multiple layers formed of different metals or metal alloys. The metallic frame 30 may also be composed of multiple layers formed of one or more metallic layers and one or more polymer layers. The relative thickness of the metallic frame 30 may vary and may depend on the materials and the process used to form the metallic frame 30. Additionally, ambient conditions and the application of the OLED structure 20 may be design considerations for the thickness of the metallic frame 30. In general, the relative thickness of the metallic frame 30 is less than the thickness of the flexible substrate 40 and does not interfere with the transmission of light from the OLED 50. In one aspect of the disclosure, the metallic frame 30 may have a thickness ranging from about 0.1 μm to about 5 mm.

The metallic frame 30 may be formed by various deposition methods known. to those skilled in the art. Deposition methods may include, but are not limited to, physical vapor deposition, chemical vapor deposition, thermal vapor deposition, sputter deposition, or atomic layer deposition. In one aspect of the disclosure, the metallic frame 30 is formed using shadow mask deposition. The metallic frame 30 may also be formed as a single layer or multiple layer film using lamination. The metallic frame 30 may be a film that is attached to the lateral surfaces 25 of the organic light emitting device 20 using an adhesive.

The metallic frame 30 provides several benefits to the OLED structure 20. The metallic frame 30 encapsulates the lateral surfaces 25 of the OLED structure 20 by preventing the passage of gas and/or moisture to the OLED 50 through the lateral surfaces 25 of the OLED structure 20. As set forth above, exposure of the OLED structure 20 to gas and/or moisture causes significant damage to the OLED components. The lateral surfaces 25 of the OLED structure 20 are particularly ⁻vulnerable to gas and moisture permeation. Therefore, using the metallic frame 30 to protect the OLED structure 20 from moisture and/or gas will prevent damage and ultimately prolong the service of the OLED structure 20. In one aspect of the disclosure, an OLED assembly 10 having a metallic frame 30 has a moisture permeability less than 1×10⁻⁶ g/m² day and an oxygen permeability less than 1×10⁻⁵ g/m² day.

The metallic frame 30 may also increase the light efficiency of the organic light emitting device 20. Typically, the OLED 50 emits light in all directions. Some of the light may be emitted directly from the OLED structure 20 for example, through the flexible substrate 40 or through the desiccant layer 60 and encapsulation layer 70. Some light may be emitted into the OLED structure 20 and is either reflected back out or is absorbed. Some of the light may be emitted laterally, trapped, and absorbed by the various layers comprising the OLED structure 20. The metallic frame 30. however, may prevent the loss of light in this manner.

In one aspect of the disclosure, the metallic frame 30 may be configured to guide light within the OLED structure 20 such that the light is transmitted through the flexible substrate 40 or the encapsulation layer 70. The metallic frame 30, for example, may be highly reflective or composed of a high reflective material. The metallic frame 30 may have an inner surface 35 facing the lateral surface 25 of the OLED structure 20 that may be highly reflective or composed of a highly reflective material. For example, the arrows shown in FIG. 1 illustrate a direction and path for light generated from the OLED 50 and reflected by the metallic frame 30. As shown, the OLED 50 may generate light in the lateral direction towards the metallic frame 30. The arrows in FIG. I show that the light may then be reflected from the metallic frame 30 and transmitted through the flexible substrate 40, The light emitted from the OLED 50 may also be reflected from the metallic frame 30 and transmitted through the encapsulation layer 70.

### Encapsulation Layer

The OLED assembly 10 may further include an encapsulation layer 70. The encapsulation layer 70 may be disposed on the desiccant layer 60 of the OLED structure 20 opposite the flexible substrate 40. The encapsulation layer 70 may surround the desiccant layer 60 covering the lateral surfaces 25 of the OLED structure 20. Alternatively, the encapsulation layer 70 may be present only on the top surface of the desiccant layer 60, The encapsulation layer 70 may be an organic solid, an inorganic solid, or a combination of organic and inorganic solids. The encapsulation layer 70 may be flexible and may be processed as separate individual pieces, such as sheets or wafers, or as continuous rolls. Suitable materials for the encapsulation layer 70 materials may include glass, plastic, metal, ceramic, semiconductor, metal oxide, metal nitride, metal sulfide, semiconductor oxide, semiconductor nitride, semiconductor sulfide, carbon or combinations thereof.

In some aspects of the disclosure, the encapsulation layer 70 or a portion of the encapsulation layer 70 may be light transmissive such that the OLED structure 20 is a top-emitting device. Portions of that encapsulation layer 70 may also be opaque such that there are non-emitting regions of the OLED structure 20. The encapsulation layer 70 may be a homogeneous mixture of materials, a composite of materials, multiple layers of materials, or an assembly of multiple materials.

In one aspect of the disclosure, the encapsulation layer 70 and the metallic frame 30 may have the same composition. In other aspect of the disclosure, the metallic frame 30 may be a multi-layered film that includes the encapsulation layer 70. In some aspects of the disclosure, the metallic frame 30 may extend beyond the lateral surfaces 25 of the OLED structure 20. For example, the metallic frame 30 may extend to the lateral surfaces of the encapsulation layer 70. The metallic frame 30 may also cover the encapsulation layer 70.

### Surface Patterns

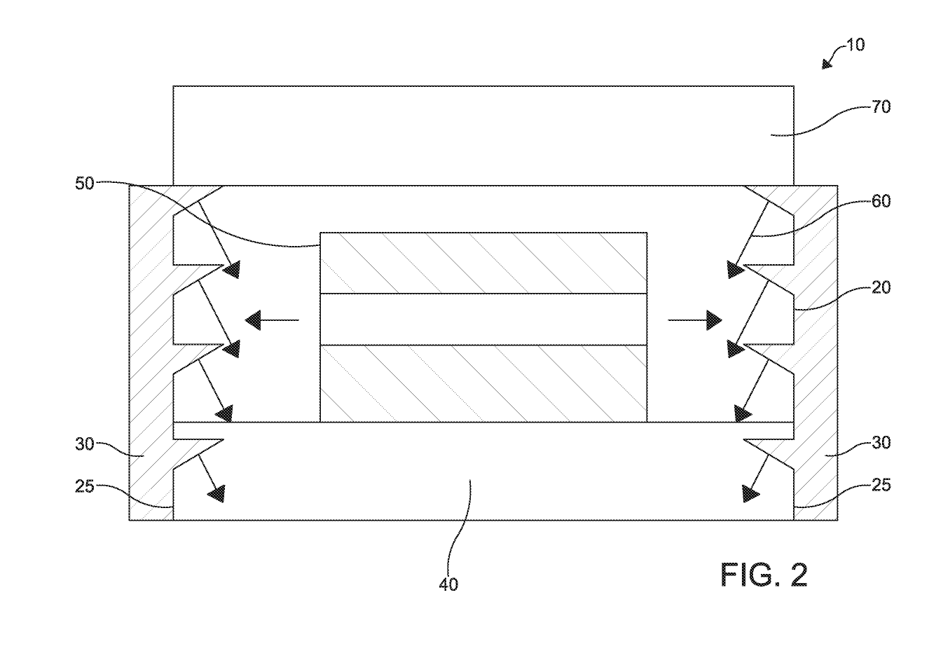

In one aspect of the disclosure, the metallic frame 30 may have surface patterns 100. For example, the surface patterns 100 may be formed on the inner surface 35 of the metallic frame 30 facing the lateral surface 25 of the OLED structure 20. FIG, 2 illustrates an example of an OLED assembly 10 with a metallic frame 30 having surface patterns 100 formed on the inner surface 35 of the metallic frame 30, In FIG. 2, the surface patterns 100 have been exaggerated for clarity of illustration. In one aspect of the disclosure, the surface patterns 100 may have a plurality of protruding features 102. As shown in FIG. 2, these protruding features 102 may protrude from the inner surface 35 of the metallic frame 30 into portions of the OLED structure 20. The protruding features 102 may, for example, protrude into portions of the flexible substrate 40 and the desiccant layer 60.

In one aspect of the disclosure, the surface patterns 100 may be configured to internally guide light emitted from the MED 50 to outside of the OLED structure 20. The surface patterns 100 may guide light emitted from the OLED 50 through the flexible substrate 40. The surface patterns 100 may also guide light emitted from the OLED 50 through the encapsulation layer 70. In one aspect of the disclosure, the surface patterns 100 may also be configured to avoid obstructing the transmission of light from the OLED 50.

In FIG. 2, the light emitted from the OLED 50 may be reflected from the protruding features 102 of the surface patterns 100 on the metallic frame 30. The light reflected from the protruding features 102 may then pass through the flexible substrate 40. The arrows shown in FIG. 2 illustrate how the light from the OLED 50 may be reflected and directed outward through the flexible substrate 40. The shape and arrangement of the protruding features 102 is not limited and may be designed to direct the light emitted from the OLED 50 in a desired direction or even a specific location.

In one aspect of the disclosure, the surface patterns 100 may intensify the reflection of light, Generally, the surface patterns 100 may increase the number of light reflecting surfaces that are present in the OLED structure 20, thereby increasing the probability that the light emitted from the OLED 50 will be directed outside the OLED structure 20.

Surface patterns 100 on the metallic frame 30 may be produced by a variety of methods known to persons skilled in the art. In one aspect of the disclosure, surface patterns 100 are formed on the metallic frame 30 using shadow mask deposition, sputtering or vacuum deposition. Alternatively, the surface patterns 100 on the metallic frame 30 may be formed using various coating methods.

### Fabrication

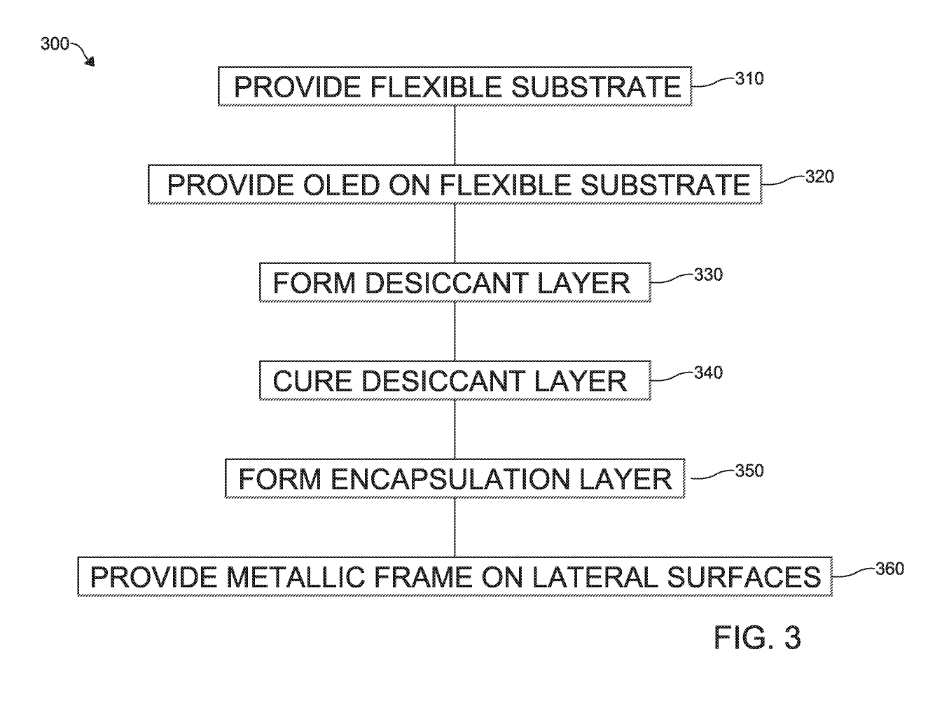

FIG. 3 is a block diagram describing the process steps of fabricating an OLED assembly 10 according to an aspect of the disclosure. The process 300 may begin with step 310 by providing a flexible substrate 40. In step 320, an OLED 50 is provided on the flexible substrate 40, As described above, the OLED 50 may have a first electrode 52, a second electrode 54 and an organic electroluminescent layer 56 disposed between the first electrode 52 and the second electrode 54. In one aspect of the disclosure, the first electrode 52, the second electrode 54 and the organic electroluminescent layer 56 may be coated onto the flexible substrate 40.

In step 330, the desiccant layer 60 surrounding the OLED 50 is formed. The desiccant layer 60 may be formed using a coating process. The desiccant layer 60 may include a desiccant material and an adhesive as described above. The desiccant layer 60 surrounds the OLED 50 so that the desiccant can effectively absorbs any moisture or gas that may be present or may permeate through the OLED structure 20. The desiccant layer 60 may also be formed to cover portions of the flexible substrate 40, such as the top surface and the lateral surfaces 25 of the flexible substrate 40.

In step 340, the desiccant layer 60 may be cured using either light or heat. In one aspect of the disclosure, the desiccant layer 60 may be cured upon exposure to UV light. In step 350, the encapsulation layer 70 is formed. The encapsulation layer 70 may be formed by lamination or deposition. The encapsulation layer 70 may be formed as a film that is subsequently laminated to the OLED structure 20. Alternatively, the encapsulation layer 70 may be formed by known deposition methods such as, for example, thermal vapor deposition, sputter deposition, or atomic layer deposition.

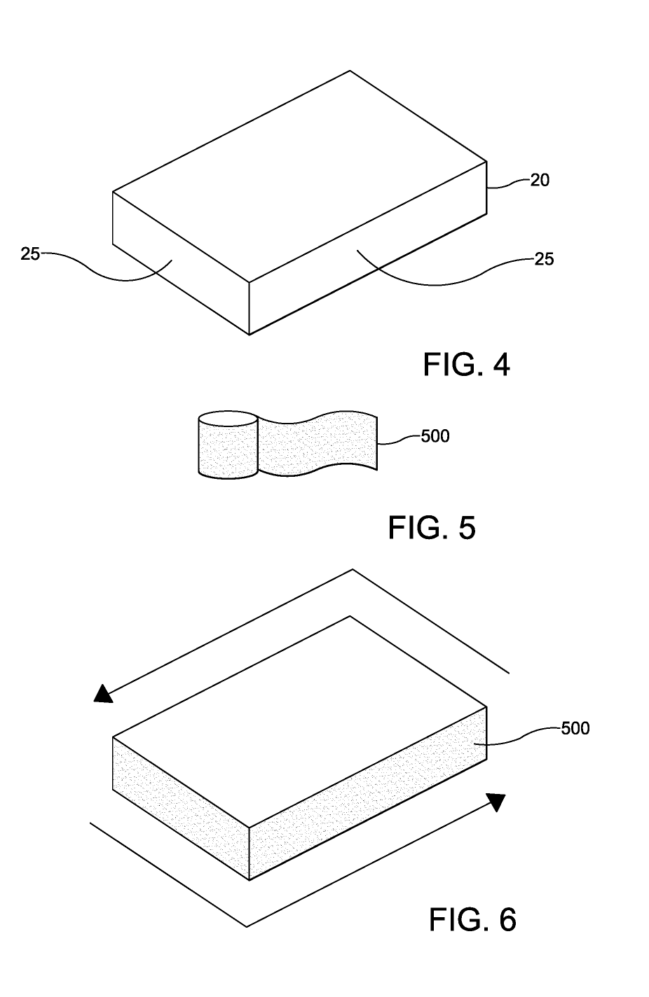

In step 360, the metallic frame 30 is formed on the lateral surfaces 25 of the OLED structure 20. The metallic frame 30 may be formed by either lamination or deposition. FIGS. 4, 5 and 6 are schematic illustrations of using lamination to form the metallic frame 30 to the lateral surfaces 25 of the OLED structure 20. The OLED structure 20 is shown in FIG. 4. The metallic frame 30 may initially be formed as a film 500 as shown in FIG. 5. The film 500 may be subsequently laminated to the lateral surfaces 25 of the OLED structure 20 as shown by the arrows in FIG. 6. An adhesive (not shown) may be used to adhere the film 500 to the lateral surfaces 25 of the OLED structure 20.

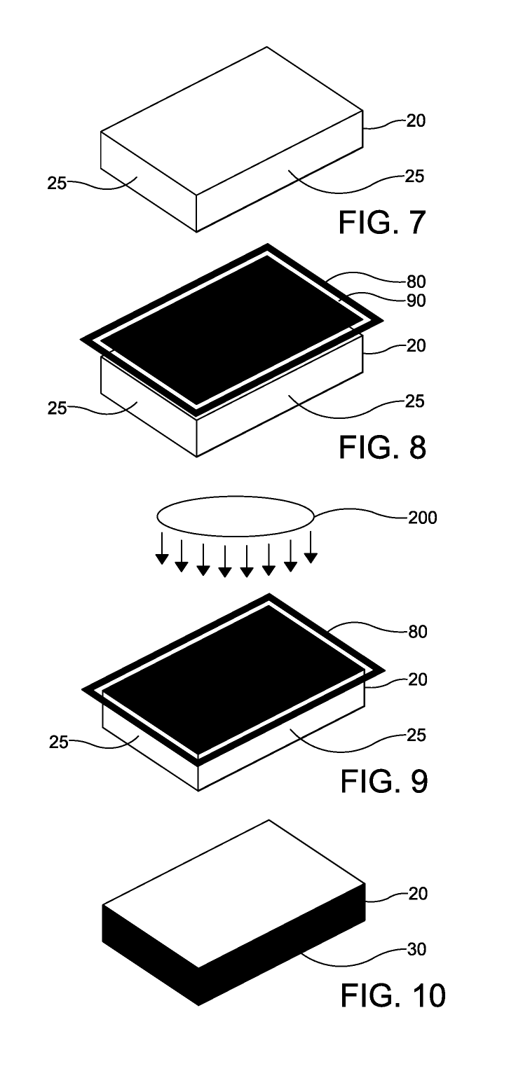

Alternatively, the metallic frame 30 may be formed by known deposition methods such as, for example, shadow mask deposition, thermal vapor deposition, sputter deposition, or atomic layer deposition. FIGS. 7-10 show a schematic illustration of using shadow mask deposition to form the metallic frame 30. In FIG. 7, an OLED structure 20 without the metallic frame 30 is shown. In FIG. 8, a shadow mask 80 is aligned with and positioned over the OLED structure 20. The shadow mask 80 has an opening 90 matching the lateral surfaces 25 of the OLED structure 20. In FIG. 9, the OLED structure 20 with the shadow mask 80 positioned over the OLED structure 20 is subjected to a deposition source 200 indicated by the arrows. The deposition source 200 is charged with the desired material to be deposited onto the lateral surfaces 25 of the OLED structure 20. The desired material from the deposition source 200 forms the metallic frame 30. In FIG. 10, the shadow mask 80 has been removed from the OLED structure 20. As shown, the metallic frame 30 has been formed on the lateral surfaces 25 of the OLED structure 20. it will be understood that there are numerous variations of these process steps that are possible and the disclosure is not limited to the process steps described above.

It will be appreciated that the foregoing description provides examples of the disclosed system and technique. However, it is contemplated that other implementations of the disclosure may differ in detail from the foregoing examples. All references to the disclosure or examples thereof are intended to reference the particular example being discussed at that point and are not intended to imply any limitation as to the scope of the disclosure more generally. All language of distinction and disparagement with respect to certain features is intended to indicate a lack of preference for those features, but not to exclude such from the scope of the disclosure entirely unless otherwise indicated.

### Definitions

It is to be understood that the terminology used herein is for the purpose of describing particular aspects only and is not intended to be limiting. As used in the specification and in the claims, the term “comprising” can include the embodiments “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural equivalents unless the context clearly dictates otherwise. Thus, for example, reference to “a polycarbonate polymer” includes mixtures of two or more polycarbonate polymers.

As used herein, the term “combination” is inclusive of blends, mixtures, alloys, reaction products, and the like.

Ranges can be expressed herein as from one particular value to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±5% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the disclosure. Thus, if there are a variety of additional steps that can be performed it is understood that each of these additional steps can be performed with any specific aspect or combination of aspects of the methods of the disclosure.

As used herein, the term “transparent” means that the level of transmittance for a disclosed composition is greater than 50%. In some embodiments, the transmittance can be at least 60%, 70%, 80%, 85%, 90%, or 95%, or any range of transmittance values derived from the above exemplified values. In the definition of “transparent”, the term “transmittance” refers to the amount of incident light that passes through a sample measured in accordance with ASTM D1003 at a thickness of 3.2 millimeters.

The term “adhesive” as used herein refers to a sticky, gluey or tacky substance capable of adhering two films together. In preferred embodiments, the adhesive is transparent. In the adhesive, desiccant material can be added for improving WVTR property. Ultraviolet (UV) or thermal energy may be necessary for curing adhesive layer.

Unless otherwise stated to the contrary herein, all test standards are the most recent standard in effect at the time of filing this application.

### Aspects

The present disclosure comprises at least the following aspects.

Aspect 1. An OLED assembly comprising: (a) an OLED structure having lateral surfaces, the OLED structure including a flexible substrate, an OLED disposed on the flexible substrate, and a desiccant layer surrounding the OLED, the OLED comprising a first electrode, a second electrode and an organic electroluminescent layer disposed between the first and second electrodes; and (b) a metallic frame arranged around the OLED structure wherein the metallic frame covers the lateral surfaces of the OLED structure.

Aspect 2. The OLED assembly of Aspect 1, wherein the desiccant layer comprises a desiccant and an adhesive.

Aspect 3. The OLED assembly of Aspect 1 or Aspect 2, further comprising an encapsulation layer disposed on the surface of the OLED structure opposite the flexible substrate.

Aspect 4. The OLED assembly of Aspect 3, wherein the metallic frame extends beyond the lateral surfaces of the OLED structure to cover at least a portion of the encapsulation layer.

Aspect 5. The OLED assembly of any one of Aspects 1-4, wherein the desiccant layer covers the flexible substrate.

Aspect 6. The OLED assembly of Aspect 5, wherein the metallic frame covers the desiccant layer.

Aspect 7. The OLED assembly of Aspect 6, further comprising an encapsulating layer interposed between the metallic frame and the desiccant layer.

Aspect 8. The OLED assembly of any one of Aspects 1-7, wherein the metallic frame comprises aluminum, nickel, copper, silver, tin, gold, chromium, cobalt, or alloys thereof.

Aspect 9. The OLED assembly of any one of Aspects 1-8, wherein the metallic frame comprises a metal and a polymer.

Aspect 10. The OLED assembly of any one of Aspects 1-9, wherein the metallic frame is flexible.

Aspect 11. The OLED assembly of any one of Aspects 1-10, further comprising an adhesive layer interposed between at least one lateral surface of the OLED structure and the metallic frame.

Aspect 12. The OLED assembly of any one of Aspects 1-11, wherein the metallic frame extends to cover the surface of the OLED structure opposite the flexible substrate.

Aspect 13. The OLED assembly of any one of Aspects 1-12, wherein the metallic frame is a film having a thickness ranging from about 0.1 μm to about 5 mm.

Aspect 14. The OLED assembly of any one of Aspects 1-13, wherein the metallic frame is configured to reflect light emitted from the OLED structure.

Aspect 15. The OLED assembly of any one of Aspects 1-14, wherein the metallic frame is reflective.

Aspect 16. The OLED assembly of any one of Aspects 1-15, wherein the inner surface of the metallic frame facing the lateral surface of the OLED structure is reflective.

Aspect 17. The OLED assembly of any one of Aspects 1-16, wherein the metallic frame is configured to prevent passage of gas and liquid to the OLED structure.

Aspect 18. The OLED assembly of any one of Aspects 1-17, wherein the inner surface of the metallic frame facing the lateral surface of the OLED structure has surface patterns.

Aspect 19. The OLED assembly of Aspect 18, wherein the surface patterns comprise a plurality of features protruding from the inner surface of the metallic frame.

Aspect 20. The OLED assembly of any one of Aspects 1-19, wherein the metallic frame is a film formed on the lateral surfaces of the OLED structure by lamination or deposition.

Aspect 21. The OLED assembly of Aspect 20, wherein the metallic frame is formed using vacuum deposition or shadow mask deposition.

Aspect 22. The OLED assembly of any one of Aspects 1-21, wherein at least one of the encapsulation layer and the desiccant layer are transparent.

Aspect 23. The OLED assembly of any one of Aspects 1-22, wherein the flexible substrate is transparent.

Aspect 24. The OLED assembly of any one of Aspects 1-23, wherein the moisture permeability is less than 1×10⁻⁶ g/m² day and the oxygen permeability is less than 1×10⁻⁵ g/m² day.

Aspect 25. An OLED assembly comprising:
(a) an OLED structure including a flexible substrate, an OLED disposed on the flexible substrate, and a desiccant layer surrounding the OLED and the flexible substrate, the OLED comprising a first electrode, a second electrode and an organic electroluminescent layer disposed between the first and second electrodes; and
(b) a metallic frame arranged around the OLED structure wherein the metallic frame covers the lateral surfaces of the OLED structure.

Aspect 26. The OLED assembly of Aspect 25, wherein the metallic frame covers the desiccant layer.

Aspect 27. The OLED assembly of any one of Aspects 25-26, further comprising an encapsulating layer interposed between the metallic frame and the desiccant layer.

Aspect 28. A process of fabricating an OLED assembly comprising: (a) forming an OLED structure, including providing a flexible substrate, providing an OLED on the flexible substrate, and forming a desiccant layer surrounding the OLED, wherein the OLED comprises a first electrode, a second electrode and an organic electroluminescent layer disposed between the first and second electrodes; and (b) forming a metallic frame around the OLED structure, including covering the lateral surfaces of the OLED structure with the metallic frame.

Aspect 29. The process of Aspect 28, wherein the desiccant layer of the OLED structure comprises an adhesive and a desiccant.

Aspect 30. The process of Aspect 28 or Aspect 29, further comprising curing the desiccant layer using light or heat.

Aspect 31. The process of any one of Aspects 28-30, further comprising forming an encapsulation layer on the surface of the OLED structure opposite the flexible substrate.

Aspect 32. The process of Aspect 31, further comprising covering at least a portion of the encapsulation layer with the metallic frame.

Aspect 33. The process of any one of Aspects 28-32, wherein the forming a desiccant layer includes covering the flexible substrate with the desiccant layer.

Aspect 34. The process of any one of Aspects 28-33, wherein the forming a metallic frame includes covering the surface of the desiccant layer opposite from the flexible substrate.

Aspect 35. The process of any one of Aspects 28-34, further comprising providing an encapsulating layer interposed between the metallic frame and the desiccant layer.

Aspect 36. The process of any one of Aspects 28-35, wherein the forming the metallic frame includes applying an adhesive layer between the metallic frame and the lateral surfaces of the OLED structure.

Aspect 37. The process of Aspect 36, further comprising curing the adhesive layer between the metallic frame and the lateral surfaces of the OLED structure using light or heat.

Aspect 38. The process of any one of Aspects 28-37, wherein the forming a metallic frame includes covering the top surface of the OLED structure opposite the flexible substrate.

Aspect 39. The process of any one of Aspects 28-38, wherein the forming the metallic frame includes forming a film on the lateral surfaces of the OLED structure by deposition or lamination.

Aspect 40. The process of Aspect 39, wherein the deposition is atomic layer deposition or shadow mask deposition.

Aspect 41. The process of any one of Aspects 28-40, wherein the metallic frame comprises a metal and a polymer.

Aspect 42. The process of any one of Aspects 28-41, wherein the metallic frame is configured to reflect light emitted from the OLED structure.

Aspect 43. The process of any one of Aspects 28-42, wherein the metallic frame is configured to prevent the passage of gas and liquid to the OLED structure.

Aspect 44. The process of any one of Aspects 28-43, further comprising forming surface patterns on the inner surface of the metallic frame facing the lateral surface of the OLED structure.

Aspect 45. The process of Aspect 44, wherein the forming surface patterns includes forming a plurality of features protruding from the inner surface of the metallic frame.

Aspect 46. A metallic frame for encapsulating an OLED structure, wherein the metallic frame is arranged around the OLED structure and covers the lateral surfaces of the OLED structure, the OLED structure comprising a flexible substrate, an OLED disposed on the flexible substrate, and a desiccant layer surrounding the OLED, the OLED comprising a first electrode, a second electrode and an organic electroluminescent layer disposed between the first and second electrodes.

1. An organic light emitting diode (OLED), assembly comprising:
(a) an OLED structure having lateral surfaces, the OLED structure including a flexible substrate, an OLED disposed on the flexible substrate, and a desiccant layer surrounding the OLED, the OLED comprising a first electrode, a second electrode and an organic electroluminescent layer disposed between the first and second electrodes; and
(b) a metallic frame arranged around the OLED structure wherein the metallic frame covers the lateral surfaces of the OLED structure.

2. The OLED assembly of claim 1, further comprising an encapsulation layer disposed on the surface of the OLED structure opposite the flexible substrate.

3. The OLED assembly of claim 1, wherein the metallic frame comprises aluminum, nickel, copper, silver, tin, gold, chromium, cobalt, or alloys thereof.

4. The OLED assembly of claim 1, wherein the metallic frame comprises a metal and a polymer.

5. The OLED assembly of claim 1, wherein the inner surface of the metallic frame facing the lateral surface of the OLED structure has surface patterns.

6. The OLED assembly of claim 5, wherein the surface patterns comprise a plurality of features protruding from the inner surface of the metallic frame.

7. The OLED assembly of claim 1, wherein the metallic frame is flexible.

8. The OLED assembly of claim 1, wherein the metallic frame is configured to reflect light emitted from the OLED structure.

9. The OLED assembly of claim 1, wherein the inner surface of the metallic frame facing the lateral surface of the OLED structure is reflective.

10. The OLED assembly of claim 1, wherein the metallic frame is configured to prevent passage of gas and liquid to the OLED structure.

11. The OLED assembly of claim 1, wherein the moisture permeability is less than 1×10′ g/m² day and the oxygen permeability is less than 1×10⁻⁵ g/m² day.

12. A process of fabricating an organic light emitting diode (OLED) assembly comprising:
(a) forming an OLED structure, including providing a flexible substrate, providing an OLED on the flexible substrate, and forming a desiccant layer surrounding the OLED, wherein the OLED comprises a first electrode, a second electrode and an organic electroluminescent layer disposed between the first and second electrodes; and
(b) forming a metallic frame around the OLED structure, including covering the lateral surfaces of the OLED structure with the metallic frame.

13. The process of claim 12, further comprising curing the desiccant layer using light or heat.

14. The process of claim 12, further comprising forming an encapsulation layer on the surface of the OLED structure opposite the flexible substrate.

15. The process of claim 12, wherein the forming the metallic frame includes applying an adhesive layer between the metallic frame and the lateral surfaces of the OLED structure.

16. The process of claim 12, further comprising forming surface patterns on the inner surface of the metallic frame facing the lateral surface of the OLED structure.

17. The process of claim 16, wherein the forming surface patterns includes forming a plurality of features protruding from the inner surface of the metallic frame.

18. The process of claim 12, wherein the deposition is atomic layer deposition or shadow mask deposition.

19. A metallic frame for encapsulating an organic light emitting diode (OLED) structure, wherein the metallic frame is arranged around the OLED structure and covers the lateral surfaces of the OLED structure, the OLED structure comprising a flexible substrate, an OLED disposed on the flexible substrate, and a desiccant layer surrounding the OLED, the OLED comprising a first electrode, a second electrode and an organic electroluminescent layer disposed between the first and second electrodes.
